(19) United States
(12) Patent Application Publication
(10) Pub. No.: US 2008/0217633 A1
(43) Pub. Date: Sep. 11, 2008

(54) LIGHT EMITTING DIODE STRUCTURE

(76) Inventors: Wu Yin Chang, Ping-Jen (TW); Chen Tsung Lin, Ping-Jen (TW); Tseng Kuo Shu, Ping-Jen (TW); Lee Wei Chang, Ping-Jen (TW)

Correspondence Address: LOWE HAUPTMAN HAM & BERNER, LLP, 1700 DIAGONAL ROAD, SUITE 300, ALEXANDRIA, VA, 22314, US

(21) Appl. No.: 11/680,723

(22) Filed: Mar. 1, 2007

(51) Int. Cl. H01L 33/00

(52) U.S. Cl. 257/98; 257/E33.068; 257/E33.075

(57) ABSTRACT

Disclosed is a new LED structure comprising a substrate, and a light emitting die entrained on the substrate. The substrate is made of the lower temperature co-fired ceramic or high temperature co-fired ceramic. The substrate is provided with a printed circuit which can be electrically in connection with an electric circuit board when it entrains the light emitting die. On the surface of the substrate where the light emitting die is to be set, is formed of a flared annular groove which has a light reflection pallet affixed to its lower surface. The surface of the light reflection pallet is coated with the silver glue, fluorescent powder, or other metallic substances. Under the annular groove and above the substrate is interposed an insulation bottom plate to entrain the light emitting die on and the die is connected to the positive and negative electrodes of the substrate with conductors. A number of pores are formed in the substrate and filled with heat dissipation substances.

### BACKGROUND OF THE INVENTION

1. Field of the Invention

The present invention relates to light emitting diode (LED) structure, and particularly to a LED of excellent light gathering effect, low heat resistance, and rapid heat dissipation.

2. Description of the Prior Art

Traditionally, a LED die is set in a light gathering pallet affixed with a heat conducting layer, beneath the heat conducting layer is attached with a heat dissipation sheet. As the LED die in the light gathering pallet emits light, it also consumes electric energy and produces heat loss which being conducted to the heat conducting layer via the light gathering pallet, and to the heat dissipation sheet. By so, the heat resistance becomes high because the heat has to be conducted through a number of media laid in the long conduction route resulting in a poor heat dissipation speed and efficiency. The function and the life of the LED are therefore reduced by its slow heat dissipation.

For the remedy of such shortcomings, the Taiwan U.M. No. M292,161 disclosed a structure of LED in which a recess is formed at the surface of the heat dissipation sheet to entrain a LED chip. A printed circuit board is attached to the bottom of the heat dissipation sheet, and a perforation is formed on the PCB in the position corresponding to the recess. The PCB and the LED are connected with a conductor. The fringe of the recess is formed into arcuate lip configuration and the surface of the recess is covered with a light reflection layer, and the light reflection layer is further covered with a sealing gel so as to fill up the recess and the perforation of PCB as well.

The structure of the LED constructed as such is said to be advantageous by the reason that the LED die is directly put in the recess of the heat dissipation sheet so as to shorten the heat dissipation passage effective for directly dissipate the heat generated by the LED. But this cited invention is still imperfect by the following reasons:

1. To form a recess directly on the surface of the heat dissipation sheet is inept because it makes the LED not easy to be fabricated.

2. To form an arcuate lip fringe for the recess and cover with the light reflection layer will result in increasing the height of the heat dissipation sheet and the whole structural weight, and the increase of light reflection area is not significant by making the arcuate lip fringe for the recess.

3. The heat dissipation is poor by the reason that the heat dissipation sheet has a dense construction.

For rectifying these shortcomings noticeable on the prior art, the inventor of the present invention has delicate great efforts for years to study for improvement, and finally come up with this invention.

### SUMMARY OF THE INVENTION

Accordingly, it is an object of the present invention to provide a LED in which the silver glue and fluorescent powder are employed to improve the light emitting efficiency.

It is another object of the present invention to provide a LED in which the heat produced by the working LED can be rapidly dissipated by forming a porous substrate.

It is still another object of the present invention to provide a LED in which the pores in the substrate are filled with heat dissipation substances so as to facilitate heat dissipation.

The above object and other advantages of the present invention will become more apparent by describing in detail the preferred embodiments of the present invention with reference to the attached drawings.

### BRIEF DESCRIPTION OF THE DRAWINGS

The above and other objects, features and advantages of the present invention will be more apparent from the following detailed description taken in conjunction with the accompanying drawings, in which:

FIG. 1 is a perspective view of the present invention;

FIG. 2 is a longitudinal cross sectional view of the present invention;

FIG. 3 is a perspective view showing another embodiment of the present invention;

FIG. 4 is a longitudinal cross sectional view of another embodiment of present invention.

### DETAILED DESCRIPTION OF THE PREFERRED EMBODIMENTS

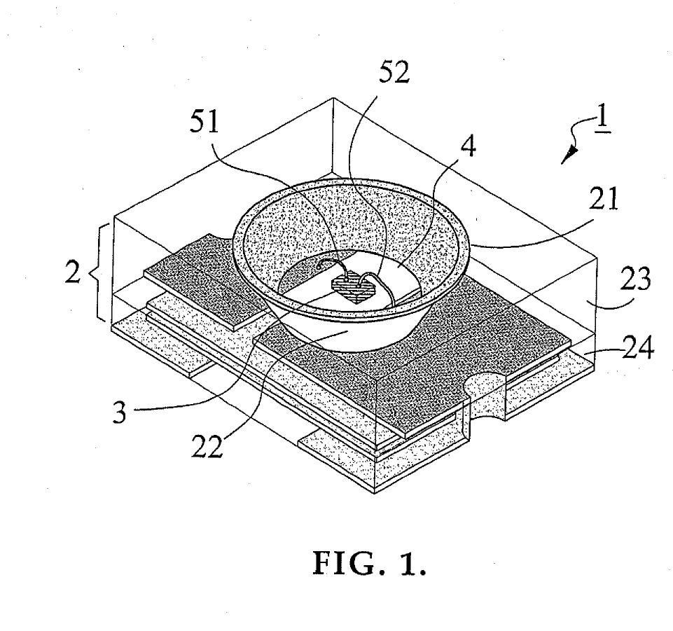

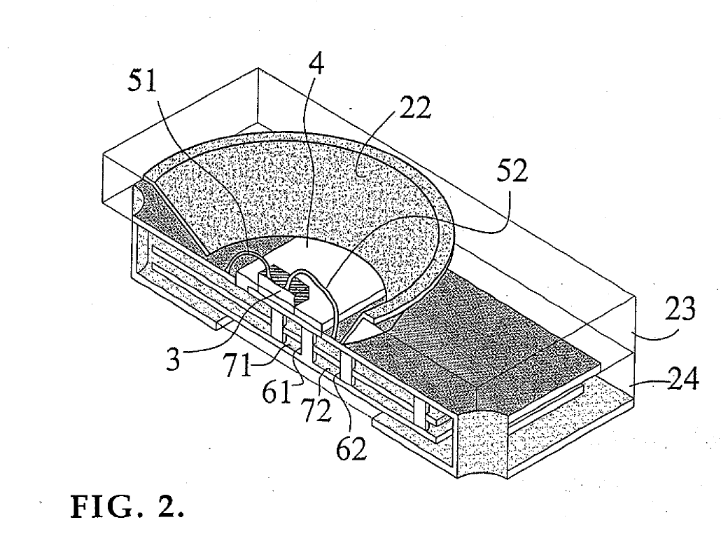

Referring to FIG. 1 and FIG. 2, the LED 1 of the present invention comprises a substrate 2, and a light emitting die 3 entrained on the substrate 2. The substrate 2 may be a low temperature co-fired ceramic (LTCC) substrate or a high temperature co-fired ceramic (HTCC) substrate. The substrate 2, which has a pre-formed electric circuit in it, is set on an electrical circuit board to be electrically in connection with each other. On the surface of the substrate 2 where the light emitting die 3 is to be set, is formed into a flared annular groove 21 which has a light reflection pallet 22 affixed to its lower surface. The surface of the light reflection pallet 22 is coated with the silver glue, fluorescent powder, or other metallic substances Under the annular groove 21 and above the substrate 2 is interposed with an insulation bottom plate 4 to entrain the light emitting die 3 on, and the light emitting die 3 is connected to the positive and negative electrodes of the substrate 2 with conductors 51 and 52. A number of pores 61, 62 are formed in the substrate 2 and can be filled with heat dissipation substances 71 and 72.

The substrate 2 is divided at least in two parts, the upper substrate 23 has an annular groove 21 for the light reflection pallet 22 to affix, on the other hand, the lower substrate 24 has a printed circuit on its surface to be electrically in connection with the light emitting die 3. The external surrounding of the light emitting die 3 including the surface of the light reflection pallet 22, is coated with a fluorescent powder which partially absorbs the light emitted from the light emitting die 3 and outputs a fluorescent light in a specified color(wave length).

Incidentally, as the surface of the light reflection pallet 22 is coated with a better light reflective silver glue so as to enhance the brilliancy and visual feeling of its light output. As for the colors of the fluorescent powder may be yellow, red, green an blue.

In addition, the lower substrate 24 is practically partitioned by numerous pores 61, 62 among which are intercalated with metallic substance, or filled with the dissipation substances 71, 72 so as to attain a better heat dissipation effect.

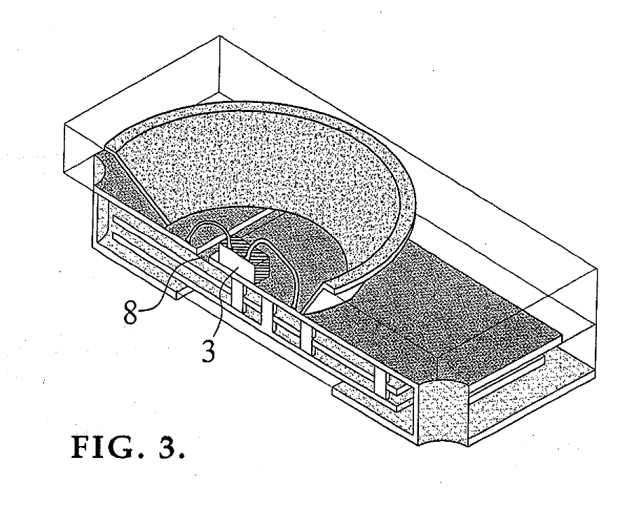

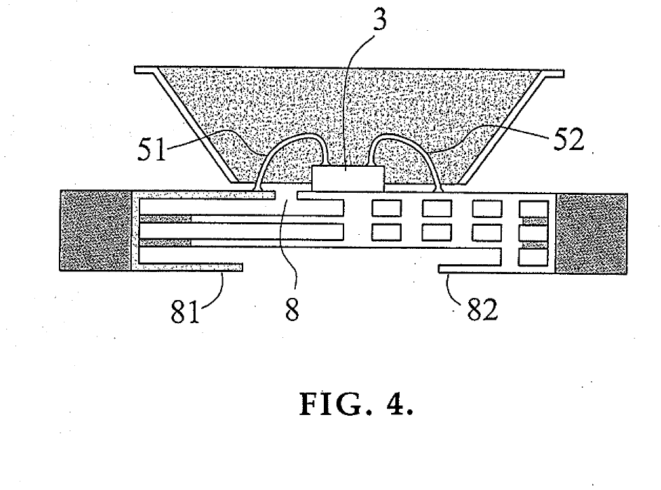

FIG. 3 and FIG. 4 show another embodiment of the present invention. In this embodiment, the light emitting die 3 is directly set on the surface of the upper substrate 23 without using the bottom plate 4, and connected to the positive and negative electrodes of the substrate 2 with the conductors 51, 52 along a partition slot 8.

As it is clearly observable from FIG. 4, the printed circuit formed on the lower substrate 24 is in connection with the terminals 81, 82 provided for the lower substrate 24 so as to be electrically connected with the electric circuit of the applied equipments. The pores 61, 62 contribute to rapidly dissipating the heat generated by the LED thereby promoting the efficiency and lifespan of the LED.

It emerges from the above description that the LED structure of the present invention is really advantageous in improving the light emitting efficiency and light color by employing the silver glue and fluorescent powder to coat the light reflection pallet, and facilitating the dissipating the heat generated from the working LED by forming a number of pores filled with the heat dissipation substance. Such prominent merits are never experienced in any LED structure according to the prior art.

While the invention has been described in terms of what are presently considered to be the most practical and preferred embodiments, it is to be understood that the invention need not be limited to the disclosed embodiments. On the contrary, it is intended to cover various modifications and similar arrangement included within the spirit and scope of the appended claims which are to be accorded with the broadest interpretation so as to encompass all such modifications and similar structures.

What is claimed is:

1. A LED structure comprising:
a substrate divided into an upper substrate and a lower substrate, said lower substrate has a printed circuit on its front and/or rear surfaces;
an annular groove formed on said upper substrate;
a light reflection pallet affixed to lower surface of said annular groove;
an bottom plate formed under said annular groove and above said lower substrate;
a light emitting die entrained on said bottom plate and electrically in connection with said printed circuit using electric conductors; and
a fluorescent powder coated on the surface of said light reflection pallet.

2. The LED structure as claimed in claim 1, wherein said substrate is a ceramic substrate.

3. The LED structure as claimed in claim 1, wherein said substrate is low temperature co-fired ceramic substrate or a high temperature co-fired ceramic substrate.

4. The LED structure as claimed in claim 1, wherein said lower substrate is porous.

5. The LED structure as claimed in claim 4, wherein said pores formed in said lower substrate are filled with at least a heat dissipation substance.

6. The LED structure as claimed in claim 4, wherein said pores formed in said lower substrate are filled with at least a heat metallic dissipation substance.
